(19) United States
(12) Patent Application Publication
(10) Pub. No.: US 2025/0273461 A1
(43) Pub. Date: Aug. 28, 2025

(54) METHOD OF FORMING SEMICONDUCTOR STRUCTURE, SEMICONDUCTOR STRUCTURE, AND SEMICONDUCTOR PROCESSING SYSTEM

(71) Applicant: ASM IP Holding B.V., Almere (NL)

(72) Inventors: Omar Elleuch, Litchfield Park, AZ (US); Chenhui Yan, Chandler, AZ (US); Yu-Jen Chiu, Tempe, AZ (US); Yanfu Lu, Phoenix, AZ (US); Caleb Miskin, Mesa, AZ (US); Alexandros Demos, Scottsdale, AZ (US)

(21) Appl. No.: 19/064,487

(22) Filed: Feb. 26, 2025

Related U.S. Application Data
(60) Provisional application No. 63/558,957, filed on Feb. 28, 2024.

(51) Int. Cl. H01L 21/02; C23C 16/48; C23C 16/52

(52) U.S. Cl. CPC H01L 21/02532; C23C 16/481; C23C 16/52; H01L 21/0262

(57) ABSTRACT

A method of forming a semiconductor structure is provided. The method includes seating a substrate in a first chamber of a semiconductor processing system, depositing a first layer pair overlaying the substrate while the substrate is seated in the first chamber of the semiconductor processing system, and removing the substrate from the first chamber. The substrate is transferred to a second chamber coupled to the first chamber of the semiconductor processing system, seated in the second chamber of the semiconductor processing system, and a second layer pair deposited on the substrate while the substrate is seated in the second chamber such that the second layer pair overlays the first layer pair. Semiconductor structures and semiconductor processing systems are also described.

### CROSS-REFERENCE TO RELATED APPLICATIONS

This application claims priority to and the benefits of U.S. Provisional Patent Application No. 63/558,957, filed on Feb. 28, 2024, the contents of which are incorporated herein by reference in their entirety.

### FIELD OF INVENTION

The present disclosure generally relates to forming semiconductor structures, and more particularly to forming semiconductor structures by depositing layer pairs onto substrates.

### BACKGROUND OF THE DISCLOSURE

Material layers are commonly deposited onto substrates by depositing layer pairs onto substrates, such as during the fabrication of semiconductor devices. Deposition is generally accomplished by loading a substrate into a reactor, heating the substrate to a desired deposition temperature, and exposing the substrate to a material layer precursor. Once the substrate develops a desired property, e.g., thickness, the substrate is typically removed from the reactor and sent on for further processing, as appropriate for the semiconductor structure being formed.

In some material layer deposition methods, deposition of the desired material layer may be accompanied by collateral deposition may accrete on interior surfaces within the reactor. The collateral deposition may require periodic removal of the reactor, such as by taking the reactor out of service for cleaning subsequent to processing the substrate and prior to processing the next substrate. While generally acceptable for its intended purpose, cleaning the reactor can interrupt substrate processing, potentially limiting throughput of the semiconductor processing system including the reactor

Such methods and systems have generally been considered suitable for their intended purpose. However, there remains a need in the art for improved methods of forming semiconductor structures, semiconductor processing systems, and semiconductor devices formed using semiconductor structures. The present disclosure provides a solution to this need.

### SUMMARY OF THE DISCLOSURE

A method of forming a semiconductor structure is provided. The method includes seating a substrate in a first chamber of a semiconductor processing system, depositing a first layer pair overlaying the substrate while the substrate is seated in the first chamber of the semiconductor processing system, and removing the substrate from the first chamber. The substrate is transferred to a second chamber coupled to the first chamber of the semiconductor processing system, seated in the second chamber of the semiconductor processing system, and a second layer pair deposited on the substrate while the substrate is seated in the second chamber such that the second layer pair overlays the first layer pair.

In addition to one or more of the features described above, or as an alternative, further examples of the method may include that depositing the first layer pair includes depositing a silicon germanium material layer and silicon material layer on the substrate. The silicon germanium material layer may overlay the substrate. The silicon material layer may be deposited onto the silicon germanium material layer.

In addition to one or more of the features described above, or as an alternative, further examples of the method may include that depositing the first layer pair may include flowing a silicon-containing material layer precursor including at least one of silane, dichlorosilane, and trisilane to the first chamber; co-flowing a germanium-containing material layer precursor with the silicon-containing material layer precursor to the first chamber; and exposing the substrate to the silicon-containing material layer precursor and the germanium-containing material layer precursor in the first chamber.

In addition to one or more of the features described above, or as an alternative, further examples of the method may include that depositing the first layer pair may include controlling temperature of the substrate during deposition of the silicon germanium material layer using electromagnetic radiation emitted by the silicon germanium material layer during deposition and received at a pyrometer supported above the first chamber. Depositing the first layer pair may include controlling temperature of the substrate during deposition of the silicon material layer using electromagnetic radiation emitted by the silicon material layer during deposition and received at the pyrometer supported above the first chamber.

In addition to one or more of the features described above, or as an alternative, further examples of the method may include depositing the silicon material layer may include flowing a silicon-containing material layer precursor including at least one of silane, dichlorosilane, and trisilane to the first chamber.

In addition to one or more of the features described above, or as an alternative, further examples of the method may include that depositing the second layer pair includes depositing a silicon germanium material layer and a silicon material layer on the substrate. The silicon germanium material layer may overlay the first layer pair. The silicon material layer may be deposited onto the silicon germanium material layer of the second layer pair and overlay the first layer pair.

In addition to one or more of the features described above, or as an alternative, further examples of the method may include depositing the second layer pair includes flowing a silicon-containing material layer precursor including at least one of silane, dichlorosilane, and trisilane to the second chamber; co-flowing a germanium-containing material layer precursor with the silicon-containing material layer precursor to the second chamber; and exposing the substrate to the silicon-containing material layer precursor and the germanium-containing material layer precursor within the second chamber.

In addition to one or more of the features described above, or as an alternative, further examples of the method may include that depositing the second layer pair includes controlling temperature of the silicon germanium material layer during deposition of the silicon germanium material layer using electromagnetic radiation emitted by the silicon germanium material layer received at a pyrometer supported above the second chamber, and controlling temperature of the silicon material layer during deposition of the silicon material layer using electromagnetic radiation emitted by the silicon material layer at the pyrometer supported above the second chamber.

In addition to one or more of the features described above, or as an alternative, further examples of the method may include that depositing the silicon material layer of the first layer pair includes flowing a silicon-containing material layer precursor including at least one of silane, dichlorosilane, and trisilane to the second chamber.

In addition to one or more of the features described above, or as an alternative, further examples of the method may include that depositing the first layer pair overlaying the substrate may include depositing between 10 and 400 first layer pairs onto the substrate while the substrate is seated within the first chamber. Depositing the second layer pair overlaying the first layer pair may include depositing between 10 and 400 second layer pairs overlaying the first layer pair on the substrate.

In addition to one or more of the features described above, or as an alternative, further examples of the method may include cleaning the first chamber during deposition of the second layer pair overlaying the first layer pair on the substrate. The method may also include that the second chamber is cleaned during deposition of the first layer pair overlaying the substrate on the substrate.

In addition to one or more of the features described above, or as an alternative, further examples of the method may include transferring the substrate further includes carrying the substrate and the first layer deposited thereon on an end effector of a substrate transfer robot supported for movement within a substrate transfer chamber coupling the first chamber to the second chamber.

In addition to one or more of the features described above, or as an alternative, further examples of the method may include that transferring the substrate from the first chamber to the second chamber further includes opening a first back-end gate valve coupling the first chamber to a substrate transfer chamber, advancing an end effector into the first chamber using a substrate transfer robot supported for movement within the substrate transfer chamber, shifting the substrate with the first layer pair deposited thereon from a substrate support within the first chamber to the end effector, and retracting the end effector carrying the substrate and the first layer deposited thereon from the first chamber through the first back-end gate valve. A second back-end gate valve coupling the second chamber to the substrate transfer chamber may be opened, and the end effector carrying the substrate and the first layer pair deposited thereon advanced into the second chamber through the second back-end gate valve.

In addition to one or more of the features described above, or as an alternative, further examples of the method may include precleaning the substrate prior to seating the substrate in the first process module.

In addition to one or more of the features described above, or as an alternative, further examples of the method may include low temperature baking the substrate within the first process chamber prior to depositing the first layer pair onto the substrate and within the first process module, and low temperature baking the substrate and the first layer pair in the second process module prior to depositing the second layer pair on the substrate and within the second process module.

In addition to one or more of the features described above, or as an alternative, further examples of the method may include offsetting a predetermined material layer deposition temperature during deposition of a plurality of first layer pairs on the substrate and within the first process chamber, and further offsetting a predetermined material layer deposition temperature during deposition of a plurality of second layer pairs on the substrate and within second process chamber.

A semiconductor structure is provided. The semiconductor structure is formed using the method described above wherein depositing the first layer pair includes controlling temperature of the silicon germanium material layer during deposition of the silicon germanium material layer using electromagnetic radiation emitted by the silicon germanium material layer received at a pyrometer supported above the first chamber and wherein controlling temperature of the silicon material layer during deposition of the silicon material layer using electromagnetic radiation emitted by the silicon material layer at the pyrometer supported above the first chamber, and wherein depositing the second layer pair includes controlling temperature of the silicon germanium material layer during deposition of the silicon germanium material layer using electromagnetic radiation emitted by the silicon germanium material layer received at a pyrometer supported above the second chamber and controlling temperature of the silicon material layer during deposition of the silicon material layer using electromagnetic radiation emitted by the silicon material layer at the pyrometer supported above the second chamber.

A semiconductor processing system is provided. The semiconductor processing system includes a substrate transfer chamber housing a substrate transfer robot, a first chamber coupled to the substrate transfer chamber, a second chamber coupled to the substrate transfer chamber and therethrough to the first chamber, and a controller. The controller is operatively coupled to the semiconductor processing system and responsive to instructions recorded on a memory to seat a substrate in a first chamber using the substrate transfer robot, deposit a first layer pair overlaying the substrate while the substrate is seated in the first chamber, remove the substrate from the first chamber using the substrate transfer robot, transfer the substrate to a second chamber using the substrate transfer robot, seat the substrate in the second chamber using the substrate transfer robot, and deposit a second layer pair overlaying the first layer pair while the substrate is seated in the second chamber.

In addition to one or more of the features described above, or as an alternative, further examples of the system may include that the instructions cause the first material layer to include a silicon germanium material layer overlaying the substrate and a silicon material layer deposited onto the silicon germanium material layer, and that the second material layer pair includes a silicon germanium material layer overlaying the first layer pair and a silicon material layer deposited onto the silicon germanium material layer of the second layer pair.

In addition to one or more of the features described above, or as an alternative, further examples of the system may include that the instructions further cause the controller to control temperature of the silicon germanium material layer during deposition of the silicon germanium material layer using electromagnetic radiation emitted by the silicon germanium material layer received at a pyrometer supported above the first chamber and control temperature of the silicon material layer during deposition of the silicon material layer using electromagnetic radiation emitted by the silicon material layer at the pyrometer supported above the first chamber.

In addition to one or more of the features described above, or as an alternative, further examples of the system may include that the instructions further cause the controller to control temperature of the silicon germanium material layer during deposition of the silicon germanium material layer using electromagnetic radiation emitted by the silicon germanium material layer received at a pyrometer supported above the second chamber and control temperature of the silicon material layer during deposition of the silicon material layer using electromagnetic radiation emitted by the silicon material layer at the pyrometer supported above the second chamber.

In addition to one or more of the features described above, or as an alternative, further examples of the system may include that the instructions further cause the controller to open a first back-end gate valve coupling the first chamber to the substrate transfer chamber, carry the substrate through the first back-end gate valve to a second back-end gate valve coupling the second chamber to the substrate transfer chamber with a substrate transfer robot supported for movement within the substrate transfer chamber, open the second back-end gate valve, and carry the substrate with the first layer pair deposited thereon through the second back-end gate valve and into the second chamber using the substrate transfer robot.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a cross-sectional side view of a semiconductor processing system in accordance with the present disclosure, schematically showing a substrate transfer chamber with a substrate transfer robot coupling a first process module to a second process module;

FIGS. 2 and 3 are cross-sectional side views of the first process module of the semiconductor processing system of FIG. 1 according to an example of the present disclosure, showing a precursor source and a chamber arrangement of the first process module, respectively;

FIGS. 4-10 are side views of the semiconductor processing system of FIG. 1 according to an example, schematically showing a first layer pair and second layer pairs being deposited on the substrate in the first process module and the second process module;

FIG. 11 is a cross-sectional side view of the semiconductor structure of FIG. 1 according to an example of the present disclosure, showing a plurality of second layer pairs deposited onto a plurality of first layer pairs of the semiconductor structure; and

FIGS. 12-15 are a block diagram of a method of forming a semiconductor structure according to an example of the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

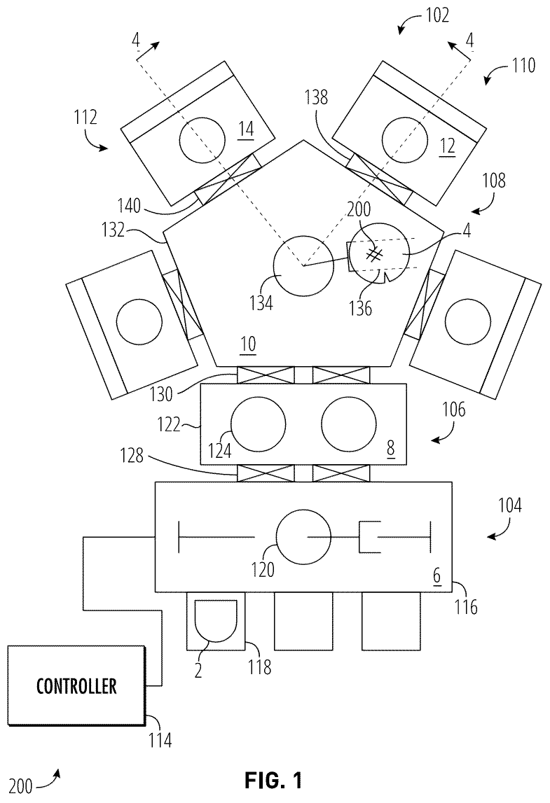

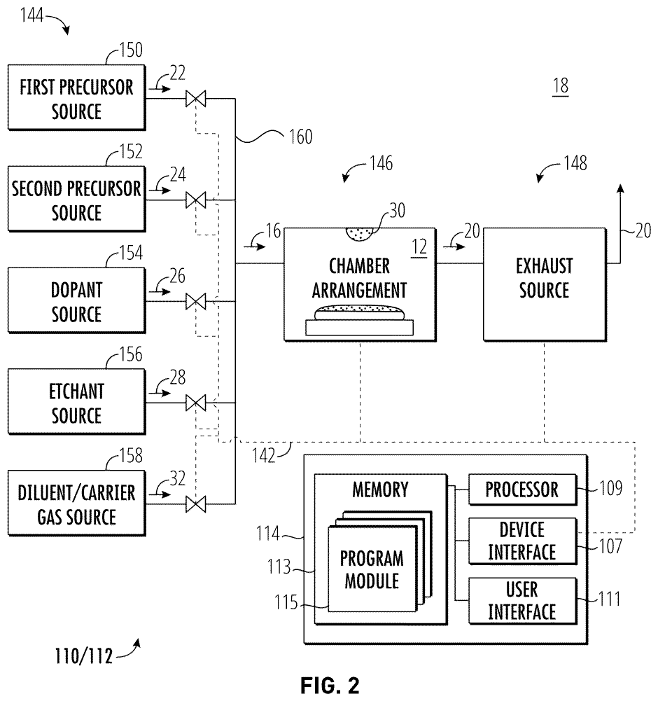

Reference will now be made to the drawings wherein like reference numerals identify similar structural features or aspects of the subject disclosure. For purposes of explanation and illustration, and not limitation, a partial view of an example of a semiconductor processing system in accordance with the present disclosure is shown in FIG. 1 and is designated generally by reference character 100. Other examples of semiconductor processing systems, semiconductor structures, and methods of forming semiconductor structures using semiconductor processing systems in accordance with the present disclosure, or aspects thereof, are provided in FIGS. 2-15, as will be described. The systems and methods of the present disclosure may be used to form semiconductor structures, such superlattices including layer pairs of silicon germanium material layers and silicon material layers epitaxial with an underlying substrate used to fabricate semiconductor devices, through the present disclosure is not limited to any particular type of layer or to semiconductor devices in general.

Referring to FIG. 1, the semiconductor processing system 100 is shown according to an example of the present disclosure. In the illustrated example the semiconductor processing system 100 has a cluster-type architecture 102 and includes an equipment front-end module (EFEM) 104, a loadlock module 106, a substrate transfer module 108, a first process module 110 (e.g., a first chamber), one or more second process module 112 (e.g., a second chamber), and a controller 114. The EFEM 104 includes an enclosure 116, one or more load port 118, and a front-end substrate transfer robot 120. The one or more load port 118 is configured to seat thereon a pod 2, e.g., a front-opening unified pod, containing one or more substrate 4, and is coupled to the loadlock module 106 by the enclosure 116. The front-end substrate transfer robot 120 is supported for movement within enclosure 116 and configured to transfer substrates, e.g., the substrate 4, between the one or more load port 118 and the loadlock module 106. The loadlock module 106 in turn couples the EFEM 104 to the substrate transfer module 108, includes a loadlock chamber body 122 housing one or more transfer stage 124, and is configured to separate an EFEM environment 6 within the enclosure 116 and a loadlock chamber environment 8 within the loadlock module 106. In this respect it is contemplated that the loadlock module 106 include a loadlock chamber body 126, the enclosure 116 may be coupled to the loadlock chamber body 126 by one or more front-end gate valve 128, and that the loadlock chamber body 126 in turn be coupled to the substrate transfer module 108 by one or more substrate transfer module gate valve 130.

The substrate transfer module 108 couples the loadlock module 106 to the first process module 110 and the second process module 112, and includes a substrate transfer chamber body 132 and a back-end substrate transfer robot 134 with an end effector 136. The back-end substrate transfer robot 134 is supported for movement within the substrate transfer chamber body 132 and is configured to transfer substrates, e.g., the substrate 4, between the loadlock module 106 and process modules of the semiconductor processing system 100 through a substrate transfer chamber environment 10 within the substrate transfer chamber body 132. In this respect it is contemplated that the substrate transfer chamber body 132 be coupled to the first process module 110 by a first back-end gate valve 138 and the second process module 112 by a second back-end gate valve 140, that the back-end substrate transfer robot 134 be configured to transfer substrates between the both the loadlock module 106 and the first process module 110 as well as the second process module 112, and that the back-end substrate transfer robot 134 further be configured to transfer substrates between the first process module 110 and the second process module 112.

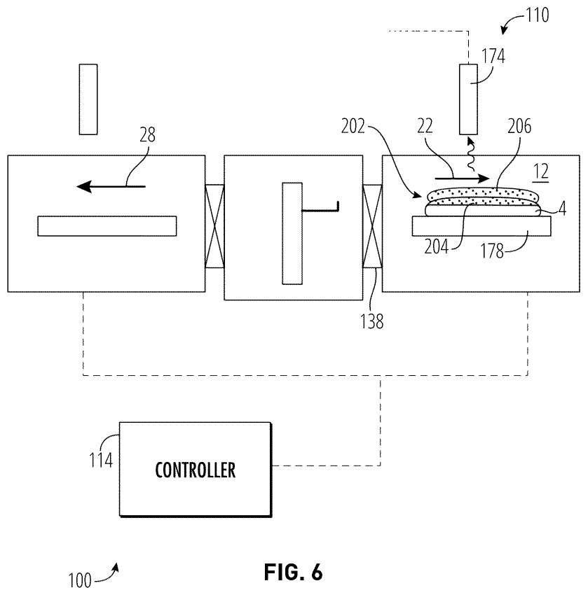

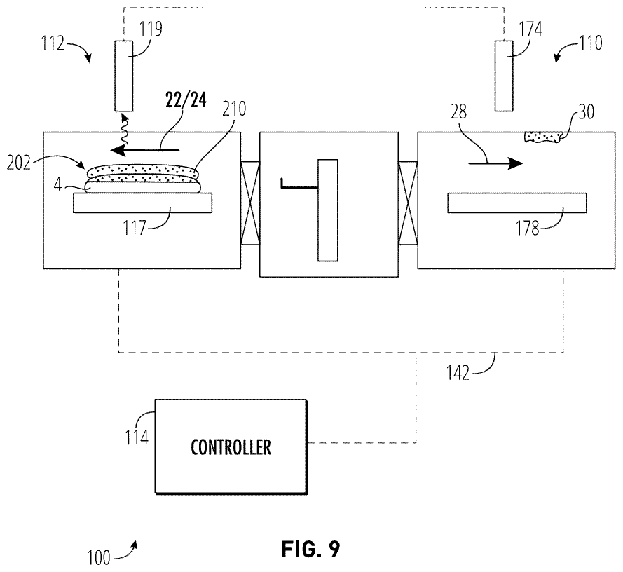

The first process module 110 and the second process module 112 are each configured to cooperatively form a semiconductor structure 200 onto the substrate 4, for example by depositing a first layer pair 202 (shown in FIG. 6) onto the substrate 4 using the first process module 110 and a second layer pair 204 (shown in FIG. 9) onto the first layer pair 202 using the second process module 112, and in this respect define therein a first process space 12 and a second process space 14, respectively. It is contemplated that the controller 114 be operatively connected to the semiconductor processing system 100 to yoke process modules of the semiconductor processing system 100 (e.g., the first process module 110 and the second process module 112) to one another, for example via a wired or wireless link 142. Although shown and described herein as having specific elements and a specific arrangement in the illustrated example, it is to be understood and appreciated that the semiconductor processing system 100 may have additional elements and/or omit certain elements shown and described herein, and/or have a different arrangement, in other examples and remain within the scope of the present disclosure.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor material such as silicon (Si), silicon-germanium (SiGe), silicon oxide (SiO₂), gallium arsenide (GaAs), gallium nitride (GaN) and silicon carbide (SiC). A substrate may include a pattern or may be unpatterned, and may include a blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the first process module 110 is shown according to an example of the present disclosure. In the illustrated example the first process module 110 includes a precursor source 144, a chamber arrangement 146, and an exhaust source 148. The precursor source 144 is coupled to the exhaust source 148 and is configured to provide a process fluid 16 to the chamber arrangement 146. The chamber arrangement 146 is configured to flow the process fluid 16 therethrough, such as to deposit a material layer onto the substrate 4 and/or to clean the first process space 12 within the chamber arrangement 146. The exhaust source 148 is in communication with an external environment 18 outside of the semiconductor processing system 100 (shown in FIG. 1), and is configured to communicate a flow of residual process fluid and/or reaction products 20 issued by the chamber arrangement 146 to the external environment 18. In certain examples, the exhaust source 148 may include one or more of abatement device like a scrubber and a vacuum pump. In such examples the exhaust source 148 may be configured to maintain a reduced pressure within the first process space 12 relative to the external environment 18, such as a predetermined material layer deposition pressure that is between about 1 Torr and 700 Torr, or between about 1 Torr and 100 Torr, or even between about 1 Torr and about 50 Torr. It is contemplated that the second process module 112 may be similar to the first process module 110 in certain examples of the present disclosure.

The precursor source 144 in turn includes a first precursor source 150, a second precursor source 152, a dopant source 154, an etchant source 156, and a diluent/carrier gas source 158. The first precursor source 150 is coupled to the chamber arrangement 146 by a process fluid supply conduit 160 and is configured to communicate a flow of one or more silicon-containing material layer precursor 22 to the chamber arrangement 146. In certain examples the one or more silicon-containing material layer precursor 22 may include a non-chlorinated silicon-containing material layer precursor. In accordance with certain examples, the one or more silicon-containing material layer precursor 22 may include a chlorinated silicon-containing material layer precursor. Examples of suitable non-chlorinated silicon-containing material layer precursors include silane (SiH₄), disilane (Si₂H₆), and trisilane (Si₃H₈). Examples of suitable chlorinated silicon-containing material layer precursors include dichlorosilane (H₂SiCl₂) and trichlorosilane (HClSi₃). It is contemplated that the first precursor source 150 may be coupled to the process fluid supply conduit 160 by a flow control device, such as flow metering valve and/or a mass flow controller (MFC) device to communicate the flow of the silicon-containing material layer precursor 22 to the chamber arrangement 146. In such examples the flow control device may be operably associated with the controller 114, such as through the wired or wireless link 142.

The second precursor source 152 is similar to the first precursor source 150 and in this respect is coupled to the chamber arrangement 146 by the process fluid supply conduit 160. It is contemplated that the second precursor source 152 be configured to provide a flow of an alloying constituent-containing material layer precursor to the chamber arrangement 146. Examples suitable alloying constituent-containing material layer precursors include germanium-containing material layer precursors such as germane (GeH₄), digermane (Ge₂H₆), trigermane (Ge₃H₈), and germylsilane (H₃Ge—SiH₃). In certain examples, the second precursor source 152 may be further configured to co-flow the alloying constituent-containing material layer precursor to the chamber arrangement 146. As will be appreciated by those of skill in the art in view of the present disclosure, co-flowing the alloying constituent-containing material layer precursor like a germanium-containing material layer precursor 24 with the silicon-containing material layer precursor 22 enables deposition silicon germanium material layers, e.g., material layers having a Si_{(1-y)}Ge_{y} composition, onto the substrate 4.

The dopant source 154 may be similar to the first precursor source 150 and additionally include a dopant-containing material layer precursor 26. The dopant source 154 may be further is configured to communicate the dopant-containing material layer precursor 26 to the chamber arrangement 146, for example through the process fluid supply conduit 160 and/or a flow control device. In certain examples, the dopant-containing material layer precursor 26 may include a p-type dopant like boron (B) and gallium (Ga). In accordance with certain examples, the dopant-containing material layer precursor 26 may include an n-type dopant-containing material layer precursor, like phosphorous (P) and arsenic (As). It is also contemplated that, in accordance with certain examples, the dopant-containing material layer precursor 26 may include a carbon-containing material layer precursor, such as methylsilane (CH₃SiH₃). As with the second precursor source 152, the dopant source 154 may be configured to co-flow the dopant-containing material layer precursor 26 to the chamber arrangement 146 with either (or both) the silicon-containing material layer precursor 22 and the alloying constituent-containing material layer precursor. In such examples material layers containing both alloying constituents and dopants may be formed, such as silicon germanium material layers doped with boron (SiGe:B material layers) and silicon germanium material layers doped with carbon (SiGe:C material layers).

The etchant source 156 is coupled to the chamber arrangement 146, for example, through the process fluid supply conduit 160, and is configured communicate an etchant 28 to the chamber arrangement 146. In certain examples, the etchant 28 may include a halogen-coating composition, such as hydrochloric (HCl) acid and chlorine (Cl₂) gas, as well as fluorine-containing compositions like hydrofluoric (HF) acid. In accordance with certain examples, the etchant source 156 may be configured to co-flow the etchant 28 to the chamber arrangement 146 with one or more of the silicon-containing material layer precursor 22, the germanium-containing material layer precursor 24, and the dopant-containing material layer precursor 26. Alternatively (or additionally), the etchant source 156 may be configured communicate the etchant 28 to the chamber arrangement 146 independently from one or more of the aforementioned material layer precursors. As will be appreciated by those of skill in the art in view of the present disclosure, co-flowing the etchant 28 with one or more of the aforementioned material layer precursors may limit (or eliminate) accretion of parasitic accretions, e.g., the parasitic accretion 30, from the first process space 12 within the chamber arrangement 146 and/or make the deposition process selective with respect composition of exposed surfaces of the substrate 4. As will also be appreciated by those of skill in the art in view of the present disclosure, flowing the etchant 28 independently from the aforementioned material layer precursors enables cleaning the chamber arrangement 146, for example to remove parasitic accretions like the parasitic accretion 30 from within the first process space 12 of the chamber arrangement 146, between successively processed substrates. As will be further be appreciated by those of skill in the art in view of the present disclosure, independent flow of the etchant 28 to the chamber arrangement 146 enable purging an interior space defined within the chamber arrangement 146, further discouraging accretion of material within such interior spaces within the chamber arrangement 146.

The diluent/carrier gas source 158 is coupled to the chamber arrangement 146 and is configured to communicate a diluent/carrier gas 32 to the chamber arrangement 146. Examples of suitable carrier/diluent fluids include hydrogen (H₂) gas. Examples of suitable inert gases also include inert gases such nitrogen (N₂) gas, noble gases like argon (Ar), helium (He), krypton (Kr), and mixtures including one or more of the aforementioned gases. In certain examples, the diluent/carrier gas source 158 may be configured to communicate the diluent/carrier gas 32 to the chamber arrangement 146 with one or more of the aforementioned material layer precursor and/or the etchant 28, for example for controlling etch rate of the etchant 28 within the chamber arrangement 146 as well as controlling fluid properties of one or more of the aforementioned material layer precursors. In accordance with certain examples, the diluent/carrier gas 32 may be provided to the chamber arrangement 146 independently of one or more of the etchant 28 and/or the aforementioned material layer precursors, for example to purge the first process space 12 within the chamber arrangement 146. Communication of the diluent/carrier gas source 158 to the chamber arrangement 146 may be through the process fluid supply conduit 160 and/or a flow metering device, which may or may not be operatively associated with the controller 114.

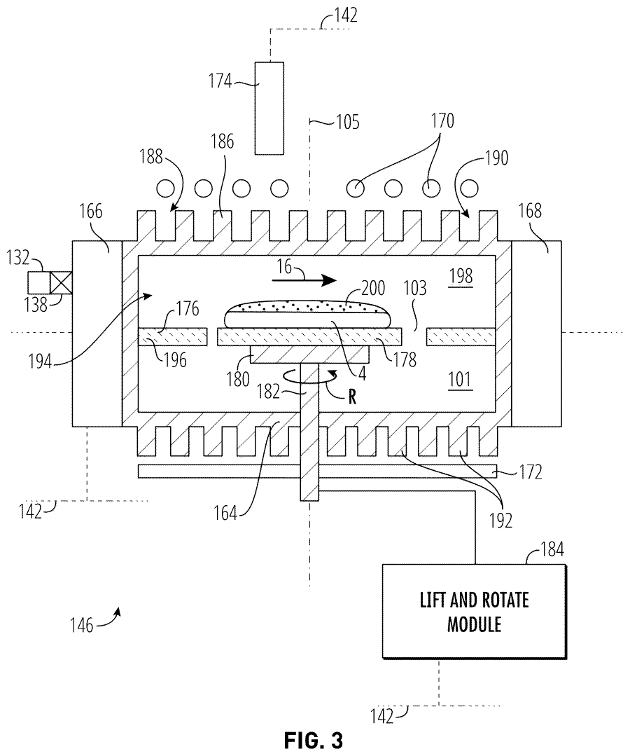

With reference to FIG. 3, the chamber arrangement 146 is shown. In the illustrated example the chamber arrangement 146 has a single-wafer crossflow architecture 162 and includes a chamber body 164, an injection flange 166, an exhaust flange 168, an upper heater element array 170, a lower heater element array 172, and a pyrometer 174. The chamber arrangement 146 also includes a divider 176, a substrate support 178, a support member 180, a shaft member 182, and a lift and rotate module 184. The chamber body 164 may be formed from a transparent material 186, e.g., a ceramic material transparent to electromagnetic radiation within an infrared waveband such as quartz, and extends longitudinally between an injection end 188 and a longitudinally opposite exhaust end 190. In certain examples, the chamber body 164 may further have a plurality of rib portions 192. In such examples the plurality of rib portions 192 may extend laterally about an exterior of the chamber body 164 and be laterally spaced apart from one another between the injection end 188 and the exhaust end 190 of the chamber body 164. It is contemplated that the injection flange 166 abut the injection end 188 of the chamber body 164, and that the injection flange 166 may further couple the precursor source 144 (shown in FIG. 2) to the chamber body 164. It is also contemplated that the exhaust flange 168 may abut the exhaust end 190 of the chamber body 164, and that the exhaust flange 168 may further couple the chamber body 164 to the exhaust source 148 (shown in FIG. 2). The injection flange 166 may be as shown and described in U.S. Pat. No. 11,053,591 to Ma et al., issued on Jul. 6, 2021, the contents of which are incorporated herein by reference in its entirety.

The upper heater element array 170 is supported above the chamber body 164 and is configured to communicate heat into an interior 194 of the chamber body 164, for example using electromagnetic radiation within an infrared waveband. In this respect the upper heater element array 170 may include a plurality of heater elements, such as linear filament-type lamps, extending laterally above the chamber body 164 and longitudinally spaced apart from one another between the injection end 188 and the exhaust end 190 of the chamber body 164. The lower heater element array 172 may be similar to upper heater element array 170, may additionally be supported below the chamber body 164, and include a plurality of linear filament-type lamps extending longitudinally between the injection end 188 and the exhaust end 190 of the chamber body 164, the plurality of linear filament-type lamps laterally spaced apart from one another between laterally opposite sides of the chamber body 164. It is contemplated that the pyrometer 174 may be supported above the chamber body 164 and configured to control heat communicated into the interior 194 of the chamber body 164, for example using electromagnetic radiation within an infrared waveband emitted by the substrate 4 and/or a material layer during deposition of the material layer onto the substrate 4. In this respect the controller 114 may operably couple the pyrometer 174 to the upper heater element array 170 and/or the lower heater element array 172, for example through the wired or wireless link 142, and the upper heater element array 170 and the lower heater element array 172 may be configured to heat structures within the interior 194 of the chamber body 164 to between about 200 and about 1200 degrees Celsius, or between about 400 and about 1200 degrees Celsius, or even between about 600 and about 1200 degrees Celsius.

The divider 176 may be formed from an opaque material 196, e.g., a ceramic material opaque to electromagnetic radiation in an infrared waveband, and may be seated within the interior 194 of chamber body 164. It is contemplated that the divider 176 divide the interior 194 of the chamber body 164 into an upper chamber 198 (which may include the first process space 12) and a lower chamber 101, that the divider 176 define a divider aperture 103 therethrough, and that the divider aperture 103 couple the upper chamber 198 to the lower chamber 101. It is further contemplated the substrate support 178 be formed from an opaque material, e.g. the opaque material 196, and that the substrate support 178 be arranged within the interior 194 of the chamber body 164 and (at least partially) within the divider aperture 103, and that the substrate support 178 may be supported within the chamber body 164 from rotation about a rotation axis 105. The support member 180 may be arranged within the lower chamber 101 of the chamber body 164 and along the rotation axis 105, may be fixed in rotation about the rotation axis 105 relative to the substrate support 178, and may couple the substrate support 178 to the shaft member 182. The shaft member 182 may in turn extend along the rotation axis 105 through a lower wall of the chamber body 164, and couple the substrate support 178 to the lift and rotate module 184.

In certain examples, the opaque material 196 may include a carbonaceous material such as graphite or pyrolytic carbon and/or a ceramic material such as silicon carbide. In accordance with certain examples, either (or both) the support member 180 and the shaft member 182 may be formed from a material transparent to electromagnetic radiation within an infrared waveband, such as the transparent material 186. It is contemplated that the lift and rotate module 184 be configured to rotate R the substrate support 178 about the rotation axis 105. It is also contemplated that the lift and rotate module 184 may be configured to seat and unseat substrates from the substrate support 178 for loading and unloading substrates from the chamber body 164, e.g., the substrate 4, and that the lift and rotate module 184 may further cooperate with the first back-end gate valve 138 and the back-end substrate transfer robot 134. In this respect the lift and rotate module 184 may cooperate with one or more lift pins slidably received within the substrate support 178 and a lift pin actuator operably associated with the substrate support 178. Examples of such lift pin and lift actuators include those shown and described in U.S. Patent Application Publication No. 2023/0116427 A1 to Su et al., filed on Oct. 7, 2022, the contents of which are incorporate herein by reference in their entirety.

With continuing reference to FIG. 2, the controller 114 may include a device interface 107, a processor 109, a user interface 111, and a memory 113. The device interface 107 couples the processor 109 to the semiconductor processing system 100, for example via the wired or wireless link 142. The processor 109 is in turn operably connected to the user interface 111 to receive user input and/or provide user output therethrough and is disposed in communication with the memory 113. The memory 113 includes a non-transitory machine-readable medium with a plurality of program modules 115 recorded the medium having instructions that, when read by the processor 109, cause the processor 109 to execute certain operations. Among the operations are operations of a method 300 of forming a semiconductor structure, e.g., the semiconductor structure 200 (shown in FIG. 1), as will be described. Although shown and described herein as having a specific arrangement and architecture, it is to be understood and appreciated that the controller 114 may have different arrangements and/or architectures in other examples of the present disclosure and remain within the scope of the present disclosure.

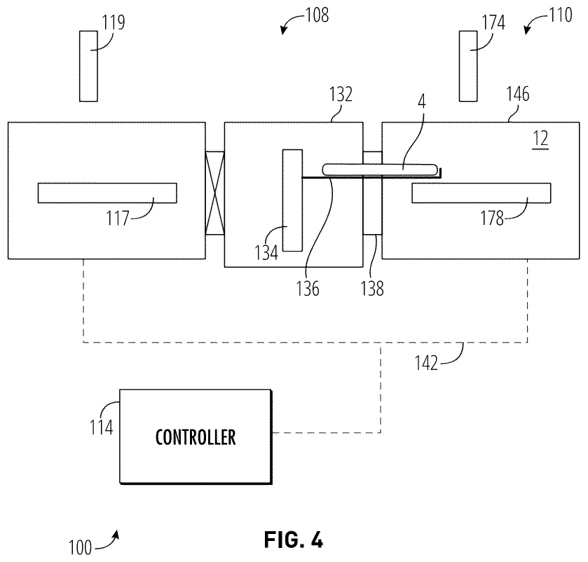

With reference to FIGS. 4-11, forming of semiconductor structure 200 by deposition of a first layer pair 202 and a second layer pair 204 onto the substrate 4 is shown according to an example of the disclosure. Referring to FIG. 4, forming the semiconductor structure 200 begins by seating the substrate 4 in the first process module 110. Seating of the substrate 4 in the first process module 110 in turn may be accomplished by opening the first back-end gate valve 138 and advancing the end effector 136 carrying the substrate 4 into the first process space 12 within the first process module 110. The substrate 4 may then be shifted to the substrate support 178, for example using lift pins slidably received in the substrate support 178, and the substrate 4 lowered onto the substrate support 178. The back-end substrate transfer robot 134 may withdraw the end effector 136 from the first process module 110 and the first back-end gate valve 138 closed to separate the first process space 12 within the first process module 110 from the substrate transfer chamber environment 10. Seating of the substrate 4 on the substrate support 178 in the first process module 110 may be accomplished using the controller 114, for example by execution of instructions by the controller 114 to devices connected to the controller 114 through the wired or wireless link 142.

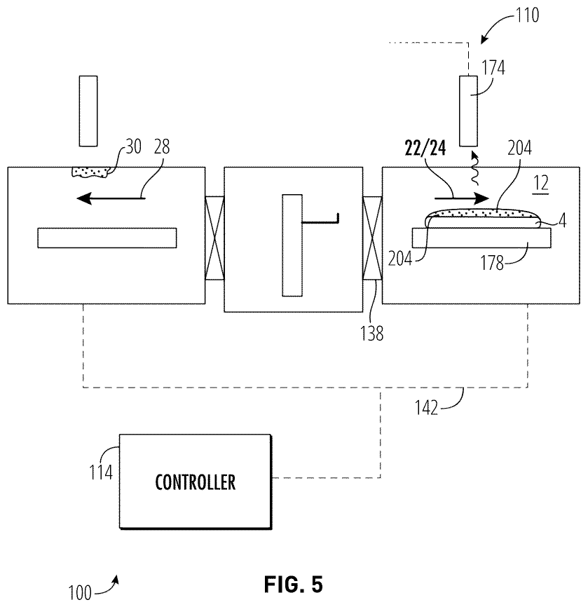

Referring to FIGS. 5 and 6, deposition of the first layer pair 202 may be accomplished by depositing a silicon germanium material layer 206 onto the substrate 4 and a silicon material layer 208 onto the silicon germanium material layer 206. As shown in FIG. 5, deposition of the silicon germanium material layer 206 may be accomplished by rotating the substrate support 178 with the substrate 4 seated thereon about the rotation axis 105 (shown in FIG. 3), heating the substrate 4 to a predetermined silicon germanium material layer deposition temperature using the upper heater element array 170 (shown in FIG. 3) and/or the lower heater element array 172 (shown in FIG. 3), and co-flowing the silicon-containing material layer precursor 22 and the germanium-containing material layer precursor 24 to the chamber arrangement 146 (shown in FIG. 2) of the first process module 110. It is contemplated that the substrate 4 be exposed to the silicon-containing material layer precursor 22 and the germanium-containing material layer precursor 24 in the first process space 12 define within the first process module 110. It is further contemplated that the substrate 4 be exposed to the silicon-containing material layer precursor 22 and the germanium-containing material layer precursor 24 under environmental conditions (e.g., temperature and pressure) selected to cause the silicon germanium material layer 206 to deposit onto the substrate 4, for example such that the silicon germanium material layer 206 is epitaxial with the substrate 4. Flow of the silicon-containing material layer precursor 22 and the germanium-containing material layer precursor 24 to the chamber arrangement 146 may thereafter cease once the silicon germanium material layer 206 reaches a predetermined silicon germanium material layer thickness, and deposition of the silicon material layer 208 onto the silicon germanium material layer 206 may thereafter commence.

As shown in FIG. 6, deposition of the silicon material layer 208 may be accomplished without removing the substrate 4 from the first process module 110. In this respect deposition of the silicon material layer 208 may be accomplished by further rotating the substrate support 178 with the substrate 4 seated thereon about the rotation axis 105 (shown in FIG. 3), heating the substrate to a predetermined silicon material layer deposition temperature using the upper heater element array 170 (shown in FIG. 3) and/or the lower heater element array 172 (shown in FIG. 3), and flowing the silicon-containing material layer precursor 22 to the chamber arrangement 146 (shown in FIG. 2) of the first process module 110. The substrate 4 may further be exposed to the silicon-containing material layer precursor 22 in the first process space 12 defined within the first process module 110 under environmental conditions (e.g., temperature and pressure) selected to cause the silicon material layer 208 to deposit onto the silicon germanium material layer 206, for example such that the silicon material layer 208 is epitaxial with the silicon germanium material layer 206. Flow of the silicon-containing material layer precursor 22 to the chamber arrangement 146 may cease once the silicon material layer 208 reaches a predetermined silicon material layer thickness, and the substrate 4 may thereafter be transferred to the second process module 112 for deposition of the second layer pair 204 onto the first layer pair 202. Deposition of the first layer pair 202 may be accomplished using the controller 114, for example via execution of instructions by the controller 114 through the wired or wireless link 142.

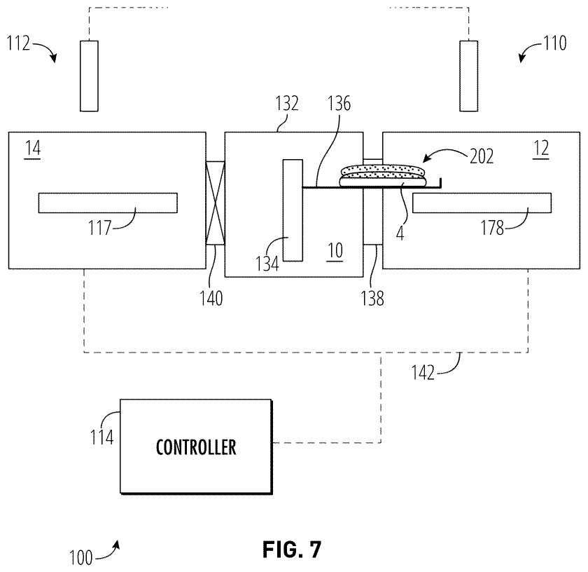

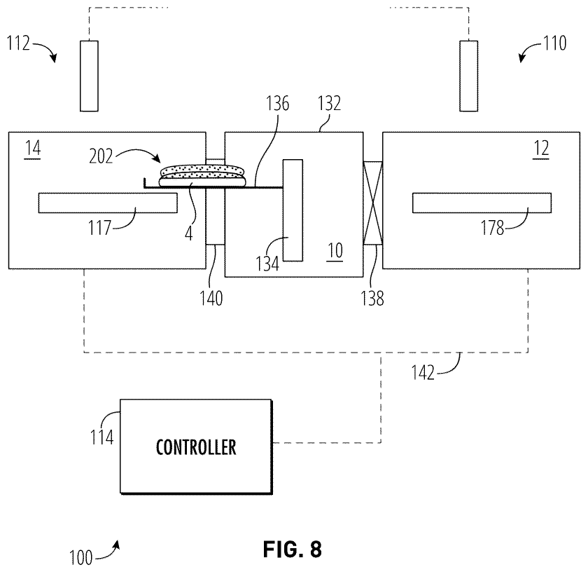

Referring to FIGS. 7 and 8, transfer of the substrate 4 with the first layer pair 202 deposited thereon is accomplished by cooperation of the back-end substrate transfer robot 134 with the first back-end gate valve 138 and the second back-end gate valve 140 to remove the substrate 4 from the first process module 110 and seat the substrate within the second process module 112. As shown in FIG. 7, removal of the substrate 4 from the first process module 110 may be accomplished by unseating the substrate 4 from the substrate support 178, for example via the plurality of lift pins slidably received in the substrate support 178, and opening the first back-end gate valve 138. The back-end substrate transfer robot 134 may thereafter advance the end effector 136 into the first process space 12 within the first process module 110, and the substrate 4 with the first layer pair 202 deposited thereon be shifted to the end effector 136. The back-end substrate transfer robot 134 may thereafter withdraw the end effector 136 with the substrate carried thereon from within the first process module 110, the first back-end gate valve 138 closed, and the back-end substrate transfer robot 134 further execute a rotary movement within the substrate transfer chamber body 132 of the substrate transfer module 108 (shown in FIG. 1) such that the end effector 136 is registered with the second back-end gate valve 140 for purposes of seating the substrate 4 with the first layer pair 202 deposited thereon within the second process module 112.

As shown in FIG. 8, seating of the substrate 4 in the second process module 112 may be accomplished by opening the second back-end gate valve 140. Once opened, the back-end substrate transfer robot 134 may advance the end effector 136 carrying the substrate 4 with the first layer pair 202 deposited thereon into the second process space 14 defined within the second process module 112. It is contemplated that the substrate 4 with the first layer pair 202 deposited thereon may then be shifted to the substrate support 178, for example using a plurality of lift pins slidably received in a substrate support 117 arranged within the second process module 112, and the substrate 4 seated by lowering the substrate 4 onto the substrate support 178. Once the substrate is shifted to the plurality of lift pins slidably received in the substrate support 117, the back-end substrate transfer robot 134 may withdraw the end effector 136 from the second process module 112, and the second back-end gate valve 140 closed to separate the second process space 14 within the second process module 112 from the substrate transfer chamber environment 10. It is contemplated that both removal of the substrate 4 within the first layer pair 202 deposited thereon from the first process module 110 and seating of the substrate 4 with the first layer pair 202 deposited thereon in the second process module 112 may be accomplished using the controller 114 by execution of instructions by the controller 114 through the wired or wireless link 142.

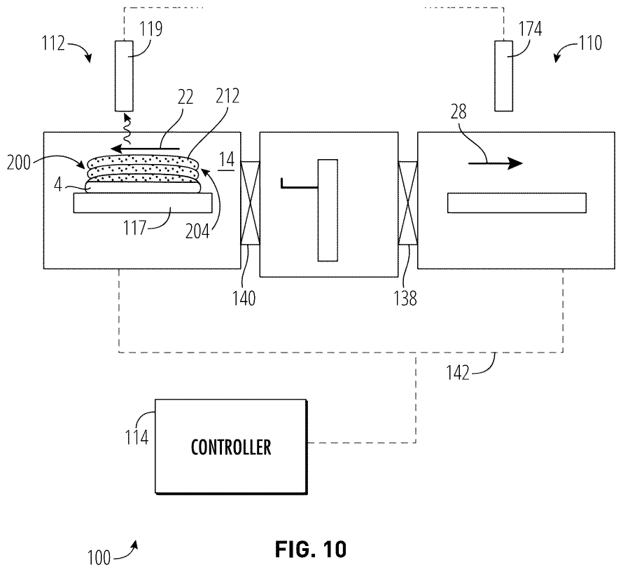

Referring to FIGS. 9 and 10, deposition of the second layer pair 204 onto the first layer pair 202 may be accomplished by depositing a silicon germanium material layer 210 onto the silicon material layer 208 and thereafter depositing a silicon material layer 212 onto the silicon germanium material layer 210. As shown in FIG. 9, deposition of the silicon germanium material layer 210 of the second layer pair 204 may be accomplished by rotating the substrate support 117 with the substrate 4 seated thereon about a rotation axis within the second process module 112, again heating the substrate 4 to the predetermined silicon germanium material layer deposition temperature using an upper heater element array and/or a lower heater element array of the second process module 112, and co-flowing the silicon-containing material layer precursor 22 and the germanium-containing material layer precursor 24 to a chamber arrangement of the second process module 112.

The substrate 4, and more particularly the silicon material layer 208 of the first layer pair 202, may again be exposed to the silicon-containing material layer precursor 22 and the germanium-containing material layer precursor 24 within the second process space 14 defined within the second process module 112 under environmental conditions (e.g., temperature and pressure) selected to cause the silicon germanium material layer 210 to deposit onto the silicon material layer 212, for example such that the silicon germanium material layer 210 is epitaxial with the silicon material layer 208 of the first layer pair 202. Flow of the silicon-containing material layer precursor 22 and the germanium-containing material layer precursor 24 to the chamber arrangement of the second process module 112 may thereafter cease once the silicon germanium material layer 210 reaches the predetermined silicon germanium material layer thickness, and deposition of the silicon material layer 212 onto the silicon germanium material layer 210 may then commence.

As shown in FIG. 10, deposition of the silicon material layer 212 of the second layer pair 204 may be accomplished without removing the substrate 4 from the second process module 112. Deposition of the silicon material layer 212 may be accomplished by further rotating the substrate support 117 with the substrate 4 seated thereon about the rotation axis within the second process module 112, again heating the substrate to a predetermined silicon material layer deposition temperature using the upper heater element array and/or the lower heater element array of the second process module 112, and flowing the silicon-containing material layer precursor 22 to the chamber arrangement of the second process module 112. It is contemplated the substrate 4, and more particularly the silicon germanium material layer 210 of the second layer pair 204, be exposed to the silicon-containing material layer precursor 22 in the second process space 14 defined within the second process module 112 under environmental conditions (e.g., temperature and pressure) selected to cause the silicon material layer 212 to deposit onto the silicon germanium material layer 210 of the second layer pair 204, for example such that the silicon material layer 212 is epitaxial with the silicon germanium material layer 210. Flow of the silicon-containing material layer precursor 22 to the chamber arrangement of the second process module 112 may thereafter cease once the silicon material layer 212 reaches the predetermined silicon material layer thickness. As above, it is further contemplated that deposition of the second layer pair 204 be accomplished using the controller 114, for example via execution of instructions by the controller 114 through the wired or wireless link 142.

In certain examples, either (or both) the silicon-containing material layer precursor 22 (shown in FIG. 2) may be co-flowed with the dopant-containing material layer precursor 26 (shown in FIG. 2) during forming of the semiconductor structure 200. In accordance with certain examples, either (or both) the silicon-containing material layer precursor 22 (shown in FIG. 2) as well as the dopant-containing material layer precursor 26 may be co-flowed with the etchant 28 (shown in FIG. 2) and/or the diluent/carrier gas 32 (shown in FIG. 2) during forming of the semiconductor structure 200. As will be appreciated by those of skill in the art in view of the present disclosure, co-flow of the dopant-containing material layer precursor 26 enables forming one or more material layer of the semiconductor structure 200 with a dopant. As will also be appreciated by those of skill in the art in view of the present disclosure, co-flowing the etchant 28 enables forming the semiconductor selectively, for example on exposed silicon surface portions of the structure while avoiding deposition onto exposed non-silicon surfaces, such as dielectric surface portions. As will further be appreciated by those of skill in the art in view of the present disclosure, co-flowing one or more of the aforementioned material layer precursors and/or the etchant 28 with the diluent/carrier gas 32 enables controlling concentration and/or fluid properties of one or more of the aforementioned material layer precursors as well as the etchant 28. To further advantage, co-flow of the etchant 28 during forming of the semiconductor structure 200 may discourage accretion of material on interior surfaces and structures within the first process module 110 and/or the second process module 112, improving reliability of the semiconductor processing system 100 and/or increasing the number of layer pairs that may be deposited in either (or both) the first process module 110 and the second process module 112.

In certain examples temperature of the substrate may be controlled during forming of the semiconductor structure 200 using electromagnetic radiation, e.g., electromagnetic radiation within an infrared waveband, emitted by a material layer of the substrate 4 and received at a pyrometer supported above the substrate 4. In this respect temperature of the substrate 4 may be controlled using electromagnetic radiation emitted by the silicon germanium material layer 206 of the first layer pair 202 during deposition of the silicon germanium material layer 206 onto the substrate 4 within the first process module 110 at the pyrometer 174. In further respect, temperature of the substrate 4 may be controlled using electromagnetic radiation emitted by the silicon material layer 208 of the first layer pair 202 onto the silicon germanium material layer 206 of the first layer pair 202 during deposition of the of silicon material layer 208 within the first process module 110 at the pyrometer 174. It is also contemplated that temperature of the substrate 4 may be controlled during deposition of the silicon germanium material layer 210 onto the silicon material layer 208 within the second process module 112 and received at a pyrometer 119, and temperature of the substrate 4 may be controlled using electromagnetic radiation emitted by the silicon material layer 212 during deposition of the silicon material layer 212 within the second process module at the pyrometer 119. Advantageously, using the pyrometer 174 and the pyrometer 119 to control temperature of the substrate 4 during forming of the semiconductor structure 200 may limit variation of properties of material layers forming the semiconductor structure 200, for example layer-to-layer mean thickness variation, that could otherwise prevent forming the semiconductor structure 200 as a singular structure using two or more process modules.

In certain examples the first process module 110 may be cleaned while the second layer pair 204 is deposited onto the substrate 4 within the second process module 112. In this respect, and as shown in FIGS. 9 and 10, the etchant 28 may be flowed to the chamber arrangement 146 subsequent to removal the substrate 4 and the first layer pair 202 deposited thereon from the first process module 110 and interior surfaces and structures within the first process space 12 exposed to the etchant 28. As will be appreciated by those of skill in the art in view of the present disclosure, coincident cleaning of the first process module 110 with continuing forming of the semiconductor structure 200 enables removal of accreted material from within the chamber arrangement 146, for example the parasitic accretion 30 within imposing que time on the substrate 4, limiting the effect that such que time could otherwise have on properties of certain material layers of the semiconductor structure 200. Moreover, as forming of the semiconductor structure 200 may continue in the second process module 112 during cleaning of the first process module, the tendency of certain deposition techniques to potentially limit the number of material layers included in the semiconductor structure 200 due to associated material accretions, and deposition techniques otherwise unsuitable for forming of the semiconductor structure 200 may therefore be employed to form semiconductor structures 200 with relatively large numbers of layer pairs, such as superlattices suitable for fabricating certain 3D DRAM devices. Similarly, as shown in FIGS. 5 and 6, the second process module 112 may also be cleaned while the first layer pair 202 is deposited onto the substrate 4 within the first process module 110 using the etchant 28 to provide further advantages with respect to the number of material layers included in the semiconductor structure 200. As will be appreciated by those of skill in the art in view the present disclosure, further layer pairs may be deposited onto the substrate 4 within the first process module 110 subsequent to cleaning, or a third process module employed to deposit further layer pairs, and remain within the scope of the present disclosure.

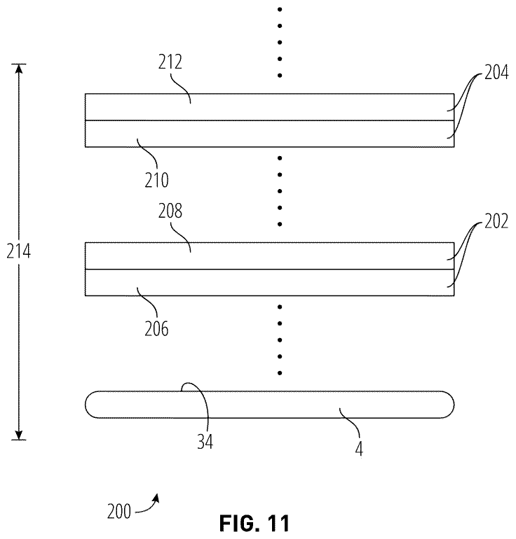

With reference to FIG. 11, the semiconductor structure 200 is shown according to an example. In the illustrated example the semiconductor structure 200 includes the substrate 4, the first layer pair 202 and the second layer pair 204. The first layer pair 202 includes the silicon germanium material layer 206 and the silicon material layer 208. In certain examples, the silicon germanium material layer 206 may be deposited onto (e.g., directly onto) an upper surface 34 of the substrate 4. In accordance with certain examples, the silicon germanium material layer 206 may be separated from the upper surface 34 of the substrate 4 by one or more first layer pairs 202, which may also be deposited on the substrate 4 while the substrate 4 is seated within the first process module 110 (shown in FIG. 1), the first layer pair 202 overlaying the substrate in such examples. The silicon material layer 212 may in turn be deposited onto (e.g., directly onto) the silicon germanium material layer 210. It is contemplated that the silicon material layer 208 may be the final material layer deposited on the substrate 4 prior to removal of the substrate 4 from the first process module 110 and transfer of the substrate 4 to the second process module 112 (shown in FIG. 1) of the semiconductor processing system 100 (shown in FIG. 1) for deposition of the second layer pair 204 on the substrate 4. It is also contemplated that the silicon germanium material layer 206 may be epitaxial (e.g., single crystal or monocrystalline) with the substrate 4, and that the silicon material layer 208 may in turn be epitaxial with the silicon germanium material layer 206.

The second layer pair 204 is deposited on the substrate 4 and includes the silicon germanium material layer 210 and the silicon material layer 212. It is contemplated that the second layer pair 204 further overlay the first layer pair 202 and in this respect the first layer pair 202 separates the second layer pair 204 from the substrate 4. In certain examples the second layer pair 204 may be deposited onto (e.g., directly onto) the first layer pair 202. In such examples the silicon germanium material layer 210 of the second layer pair 204 may be deposited onto the silicon material layer 208 of the first layer pair 202, and the silicon germanium material layer 210 of the second layer pair 204 in turn separate the silicon material layer 212 from the first layer pair 202 and the substrate 4. In accordance with certain examples, the second layer pair 204 may overlay the substrate 4 and be deposited on the substrate 4 such that one or more first layer pair and/or second layer pair separates the second layer pair 204 from the first layer pair 202. It is contemplated that the second layer pair 204 deposited while the substrate 4 is seated within the second process module 112 be substantially identical to the first layer pair 202 deposited while the substrate is seated in the first process module 110.

In certain examples, the semiconductor structure 200 may include between 2 and 400 layer pairs, or between 10 and 400 layer pairs, or between 100 and 400 layer pairs, or even between 200 and 400 layer pairs. As will be appreciated by those of skill in the art in view of the present disclosure, semiconductor structures including layer pairs within these ranges may be used to fabricate semiconductor devices having three-dimensional architectures, such as 3D DRAM devices and logic devices like CFET devices. In accordance with certain examples, the semiconductor structure 200 may have a stack height 214 that is between about 100 nanometers and about 40 microns, or between about 1 micron and about 40 microns, or even between about 10 microns and about 40 microns. Advantageously, stack heights within these ranges may, in conjunction with the aforementioned layer pair counts, impart high processing speed relative to power consumption (in the case of certain logic devices) and/or relatively high density in memory devices fabricated using the semiconductor structure. As will also be appreciated by those of skill in the art in view of the present disclosure, semiconductor structures with differing layer pair counts and/or stack heights may be formed using the systems and methods described herein and remain within the scope of the present disclosure.

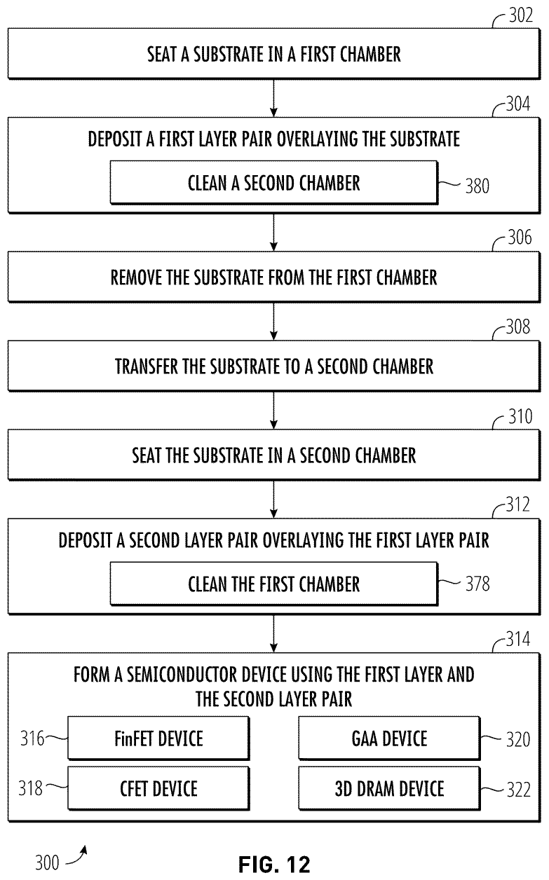

With reference to FIGS. 12-15, the method 300 of forming a semiconductor structure, e.g., the semiconductor structure 200 (shown in FIG. 1), is shown. As shown in FIG. 12, the method 300 generally includes seating a substrate in a first chamber of a semiconductor processing system and depositing a first layer pair overlaying the substrate while the substrate is seated in the first chamber of the semiconductor processing system, e.g., seating the substrate 4 (shown in FIG. 1) in the first process module 110 (shown in FIG. 1) of the semiconductor processing system 100 (shown in FIG. 1) and depositing the first layer pair 202 (shown in FIG. 11) overlaying the substrate, as shown with box 302 and box 304. The method 300 also includes removing the substrate from the first chamber and transferring the substrate to a second chamber of the semiconductor processing system, e.g., transferring the substrate from the first process module 110 to the second process module 112 (shown in FIG. 1) of the semiconductor processing system 100, as shown with box 306 and box 308. The method 300 further includes seating the substrate in the second chamber of the semiconductor processing system and depositing a second layer pair overlaying on the first layer pair while the substrate is seated in the second chamber of the semiconductor processing system, e.g., depositing the second layer pair 204 (shown in FIG. 11) on the first layer pair which the substrate 4 is seated within the second process module 112, as shown with 310 and box 312. In certain examples, a semiconductor device may be fabricated using the semiconductor structure including the first layer pair and the second layer pair, as shown with box 314. The semiconductor device may be a finFET semiconductor device, as shown with box 316. The semiconductor device may be a GAA semiconductor device, as shown with box 318. The semiconductor device may be a CFET semiconductor device, as shown with box 320. The semiconductor device may be a 3D DRAM semiconductor device, as shown with box 322. As will be appreciated by those of skill in the art in view of the present disclosure, other types of semiconductor devices may be fabricated using the semiconductor structure and remain within the scope of the present disclosure.

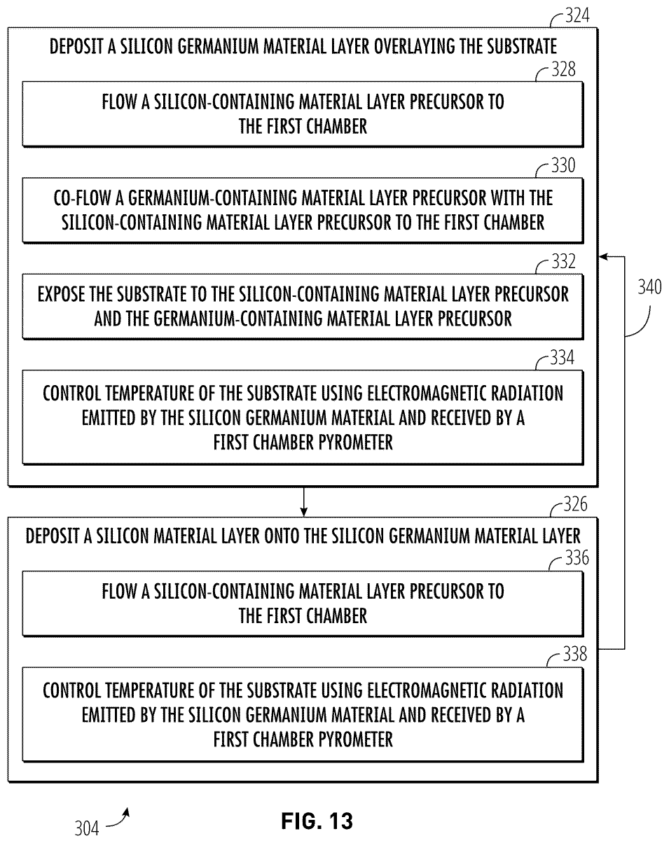

As shown in FIG. 13, depositing 304 the first layer pair overlaying the substrate may include depositing a silicon germanium material layer overlaying the substrate and a silicon material layer onto the silicon germanium material layer, e.g., the silicon germanium material layer 206 (shown in FIG. 5) and the silicon material layer 208 (shown in FIG. 6), as shown with box 324 and box 326. Depositing 324 the silicon germanium material layer overlaying the substrate may include flowing a silicon-containing material layer precursor to the first chamber, e.g., the silicon-containing material layer precursor 22 (shown in FIG. 2), as shown with box 328. Depositing 324 the silicon germanium material layer overlaying the substrate may include co-flowing a germanium-containing material layer precursor with the silicon-containing material layer precursor to the first chamber, e.g., the germanium-containing material layer precursor 24 (shown in FIG. 2), as shown with box 330. Depositing 324 the silicon germanium material layer overlaying the substrate may include exposing the substrate to the silicon-containing material layer precursor and the germanium-containing material layer under environmental conditions that cause the silicon germanium material layer to be epitaxial (e.g., single or monocrystalline) with the substrate, as shown with box 332. Depositing 324 the silicon germanium material layer overlaying the substrate may include controlling temperature of the substrate using electromagnetic radiation emitted by the silicon germanium material layer and received at a pyrometer, e.g., the pyrometer 174 (shown in FIG. 2), during deposition of the silicon germanium material layer within the first chamber, as shown with box 334.

Depositing 326 the silicon material layer onto the silicon germanium material layer may include flowing a silicon-containing material layer precursor to the first chamber, e.g., the silicon-containing material layer precursor 22 (shown in FIG. 2), as shown with box 336. Depositing 338 the silicon material layer may include controlling temperature of the substrate using electromagnetic radiation emitted by the silicon material layer and received at the pyrometer during deposition of the silicon material layer, as shown with box 340. In certain examples, the silicon-containing material layer precursor used to deposit the silicon material layer may be also used to deposit the silicon germanium material layer, as also shown with box 336. In accordance with certain examples, the silicon germanium material layer may be deposited using a silicon-containing material layer precursor not used to deposit the silicon material layer, as also shown with box 332. In certain examples, depositing 304 the first layer pair overlaying the substrate may include depositing a plurality of first layer pairs onto the substrate, as shown with arrow 334. It is contemplated that between 10 and 400 first layer pairs may be deposited onto the substrate while the substrate is seated within the first process chamber, as also shown with arrow 334.

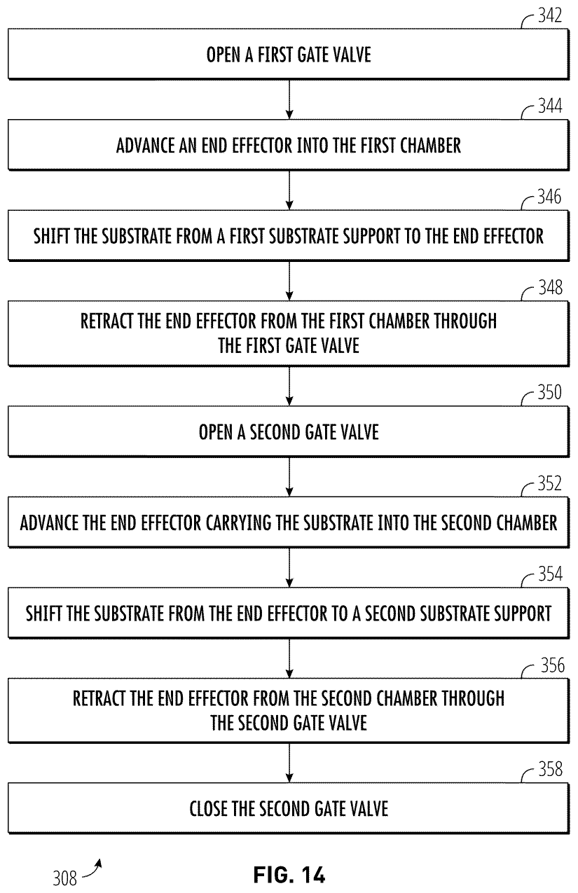

As shown in FIG. 14, transferring 308 the substrate to the second chamber may include opening a first back-end gate valve coupling the first chamber to a substrate transfer chamber, e.g., the first back-end gate valve 138 (shown in FIG. 1) coupling the first process module 110 (shown in FIG. 1) to the substrate transfer chamber body 132 (shown in FIG. 1), as shown in box 336. Once the first back-end gate valve is open, a back-end substrate transfer robot supported for movement within the substrate transfer chamber may advance an end effector through the first back-end gate valve and into the first process module, e.g., the back-end substrate transfer robot 134 (shown in FIG. 1) advance the end effector 136 (shown in FIG. 1) into the first process module, as shown with box 338. Therein the substrate may be shifted from a substrate support arranged within the first process module to the end effector, e.g., the substrate support 178 (shown in FIG. 3), and the end effector carrying the substrate with the first layer pair deposited thereon withdrawn from the first chamber through the first back-end gate valve, as shown with box 340 and box 342. It is contemplated that a second back-end gate valve coupling a second process module may then be opened, e.g., the second back-end gate valve 140 (shown in FIG. 1) coupling the second process module 112 (shown in FIG. 1) to the substrate transfer chamber body 132 (shown in FIG. 1), and the end effector carrying the substrate with the first layer pair deposited thereon be advanced through the second back-end gate valve and into the second process module, as shown with box 344 and box 346. The substrate may then be shifted to a second substrate support arranged within the second process module, e.g., the substrate support 117 (shown in FIG. 4), and the end effector retracted from the second process module, as shown with box 348 and box 350. The second back-end gate valve may then be closed, as shown with box 352, and the second layer pair deposited on the substrate such that the second layer pair overlays the first layer, as shown in box 312 (shown in FIG. 12).

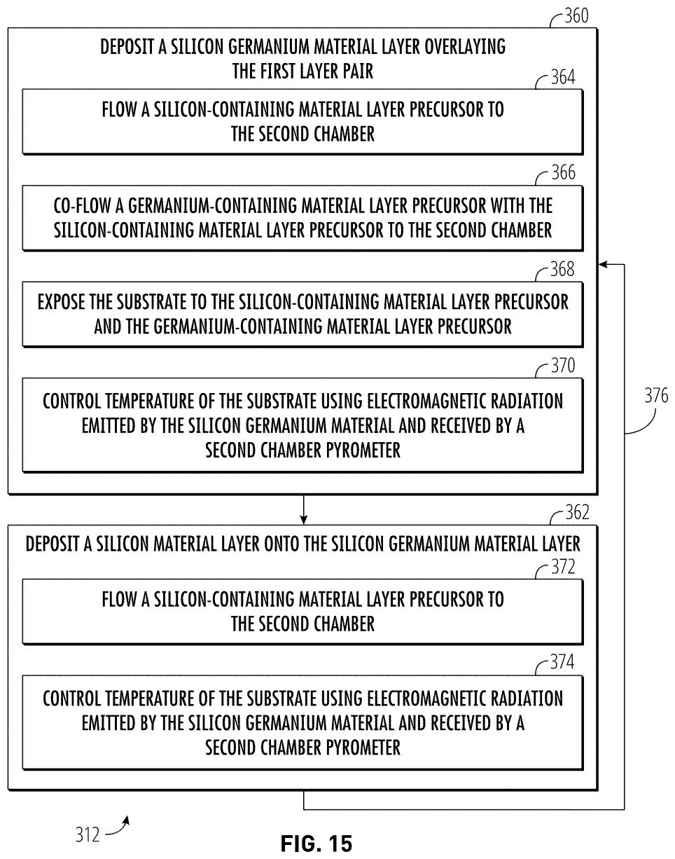

Referring to FIG. 15, depositing 312 the second layer pair overlaying the first layer pair may include depositing a silicon germanium material layer, e.g., the silicon germanium material layer 210 (shown in FIG. 9), on the substrate such that the silicon germanium material layer overlays the first layer pair, as shown with box 354. Depositing 312 the second layer pair overlaying the first layer pair may include depositing a silicon material layer onto the silicon germanium material layer, e.g., the silicon material layer 212 (shown in FIG. 10), as shown with box 356. Depositing 354 the silicon germanium material layer may include flowing a silicon-containing material layer precursor to the first chamber, as shown with box 358. The silicon-containing material layer precursor may include the same silicon-containing material layer precursor (or silicon-containing material layer precursors) as were used to deposit the silicon germanium material layer of the first layer pair, as also shown with box 358. Depositing 354 the silicon germanium material layer may include co-flowing a germanium-containing material layer precursor with the silicon-containing material layer precursor to the second chamber, as shown with box 360. The germanium-containing material layer precursor may include the same germanium-containing material layer precursor as was used to deposit the silicon germanium material layer of the first layer pair, as also shown with box 360.

Depositing 354 the silicon germanium material layer may include exposing the substrate to the silicon-containing material layer precursor and the germanium-containing material layer under environmental conditions that cause the silicon germanium material layer of the second layer pair to be epitaxial with the first layer pair, as shown with box 362. Pressure within the second chamber during deposition of the silicon germanium material layer may be substantially equivalent to pressure within the first chamber during deposition of the silicon germanium material layer of the first layer pair. Temperature of the substrate during deposition of the silicon germanium material layer may be substantially equivalent to temperature of the substrate during deposition of the silicon germanium material layer of the first layer pair. It is contemplated temperature of the substrate and the silicon germanium material layer may be controlled using electromagnetic radiation emitted by the silicon germanium material layer and received at a second chamber pyrometer, e.g., the pyrometer 119 (shown in FIG. 4) included in the second process module 112, during deposition of the silicon germanium material layer, as shown with box 364.

Depositing 356 the silicon material layer may include flowing a silicon-containing material layer precursor to the second chamber, as shown with box 366. The silicon-containing material layer precursor used to deposit the silicon material layer of the second layer pair may include flowing the same silicon-containing material layer precursor as was flowed to the first chamber to deposit the silicon material layer of the first layer pair, as also shown with box 366. The silicon-containing material layer precursor used to deposit the silicon material layer of the second layer pair may be the same as the silicon-containing material layer used to deposit the silicon material layer of the first layer pair. Pressure within the second chamber during deposition of the silicon material layer of the second layer pair may be substantially equivalent to pressure within the first chamber during deposition of the silicon material layer of the first layer pair. Temperature of the substrate during deposition of the silicon m material layer may be substantially equivalent to temperature of the substrate during deposition of the silicon germanium material layer of the first layer pair. Depositing 356 the silicon material layer may include controlling temperature of the substrate using electromagnetic radiation emitted by the silicon material layer and received at a second chamber pyrometer, e.g., the pyrometer 119 (shown in FIG. 4), during deposition of the silicon material layer onto the silicon germanium material of the second layer pair, as shown with box 368.

In certain examples, the silicon-containing material layer precursor used to deposit the silicon material layer of the second may be the same as the silicon-containing material layer used to deposit the silicon material layer of the first layer pair, as also shown with box 368. In accordance with certain examples, the silicon germanium material layer of the second layer pair may be deposited using a silicon-containing material layer precursor not used to deposit the silicon material layer of the second layer pair, as also shown with box 368. In certain examples, depositing 312 the second layer pair overlaying the first layer pair may include depositing a plurality of second layer pairs overlaying the first layer pair, as shown with arrow 370. In this respect it is contemplated that between 10 and 400 second layer pairs may be deposited onto the substrate and overlaying the first layer pair while the substrate is seated within the second process chamber, as also shown with arrow 334. It is contemplated that the first chamber may be cleaned while the second layer pair is being deposited on the substrate while the substrate is in the second chamber, as also shown with box 372.

With continuing reference to FIG. 12, the second chamber may be cleaned following deposition of the second layer pair overlaying the first layer while the substrate is seated in the second chamber, as shown with box 374. In this respect the first chamber may be cleaned while the second layer pair is being deposited on the substrate while the substrate is seated within the first chamber, as shown with box 372. Cleaning may be accomplished by flowing an etchant to the first chamber, e.g., the etchant 28 (shown in FIG. 2), and exposing a parasitic accretion 30 (shown in FIG. 2) that may have formed within the first chamber to the etchant to remove the accretion, as also shown with box 372. As will be appreciated by those of skill in the art in view of the present disclosure, removing accretions that may form during deposition within the first chamber prior to completion of forming of the semiconductor structure may prevent (or eliminate) variation that such accretions could otherwise present to the semiconductor structure formed within the first chamber. For example, removal of accretions within an optical path of the first pyrometer may limit (or prevent) such accretions from influencing properties of material layers deposited with the first chamber, such layer-to-layer mean thickness variation as well as layer pair-to-layer pair mean germanium concentration and/or dopant concentration, that could otherwise influence performance of semiconductor devices formed using the semiconductor structure. Removal of such accretions may also limit (or eliminate) risk that such accretions could otherwise pose to reliability of the first chamber, such as risk that an accretion reach a size sufficient to cause lifts pins used to shift the substrate between the first substrate support and the end effector to bind within the first substrate support.

In certain examples the substrate 4 may undergo oxide removal, as shown with box 302 in FIG. 12, such as in a preclean module coupled to the substrate transfer chamber 132 (shown in FIG. 1). In accordance with certain examples, the substrate 4 may undergo a lower temperature bake operation in either (or both) the first process module 110 and the second process module 112, as shown with box 304 and box 312, for example by heating the substrate 4 to a temperature below the predetermined material layer deposition temperature while flowing the diluent/carrier gas 32 across the substrate 4 within either (or both) the first process module 110 and the second process module 112. It is also contemplated that a temperature offset may be applied during forming of either (or both) the first layer pair 202 (shown in FIG. 6) and the second layer pair 204 (shown in FIG. 10), for example to limit the affect that the parasitic accretion 30 (shown in FIG. 2) may have on temperature control during forming of the semiconductor structure 200, as further shown with box 304 and box 312. For example, the aforementioned predetermined material layer deposition temperatures may be offset after deposition of a predetermined number of layer pairs on the substrate 4. As will be appreciated, precleaning the substrate may limit (or eliminating) native oxide, e.g., silicon oxide, that may be present on the substrate 4. As will also be appreciated by those of skill in the art in view of the present disclosure, low temperature baking may also limit (or eliminate) moisture and other contaminates that may become resident on the substrate 4 during transfer through the substrate transfer chamber environment 10, improving yield of semiconductor devices formed using the semiconductor structure 200 (shown in FIG. 1).

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A method of forming a semiconductor structure, comprising:
seating a substrate in a first chamber of a semiconductor processing system;
depositing a first layer pair overlaying the substrate while the substrate is seated in the first chamber of the semiconductor processing system;
removing the substrate from the first chamber;
transfer the substrate to a second chamber coupled to the first chamber of the semiconductor processing system;
seating the substrate in the second chamber of the semiconductor processing system; and
depositing a second layer pair overlaying the first layer pair while the substrate is seated in the second chamber of the semiconductor processing system.

2. The method of claim 1, wherein depositing the first layer pair comprises:
depositing a silicon germanium material layer overlaying the substrate; and
depositing a silicon material layer onto the silicon germanium material layer.

3. The method of claim 2, wherein depositing the first layer pair comprises:
flowing a silicon-containing material layer precursor including at least one of silane, dichlorosilane, and trisilane to the first chamber;
co-flowing a germanium-containing material layer precursor with the silicon-containing material layer precursor to the first chamber; and
exposing the substrate to the silicon-containing material layer precursor and the germanium-containing material layer precursor in the first chamber.

4. The method of claim 2, wherein depositing the first layer pair comprises:
controlling temperature of the substrate during deposition of the silicon germanium material layer using electromagnetic radiation emitted by the silicon germanium material layer during deposition and received at a pyrometer supported above the first chamber; and
controlling temperature of the substrate during deposition of the silicon material layer using electromagnetic radiation emitted by the silicon material layer during deposition and received at the pyrometer supported above the first chamber.

5. The method of claim 2, wherein depositing the silicon material layer comprises flowing a silicon-containing material layer precursor including at least one of silane, dichlorosilane, and trisilane to the first chamber.

6. The method of claim 1, wherein depositing the second layer pair comprises:
depositing a silicon germanium material layer overlaying the first layer pair; and
depositing a silicon material layer onto the silicon germanium material layer of the second layer pair.

7. The method of claim 6, wherein depositing the second layer pair comprises:
flowing a silicon-containing material layer precursor including at least one of silane, dichlorosilane, and trisilane to the second chamber;
co-flowing a germanium-containing material layer precursor with the silicon-containing material layer precursor to the second chamber; and
exposing the substrate to the silicon-containing material layer precursor and the germanium-containing material layer precursor within the second chamber.

8. The method of claim 6, wherein depositing the second layer pair comprises:
controlling temperature of the silicon germanium material layer during deposition of the silicon germanium material layer using electromagnetic radiation emitted by the silicon germanium material layer and received at a pyrometer supported above the second chamber; and
controlling temperature of the silicon material layer during deposition of the silicon material layer using electromagnetic radiation emitted by the silicon material layer during deposition and received at the pyrometer supported above the second chamber.

9. The method of claim 6, wherein depositing the silicon material layer of the first layer pair comprises flowing a silicon-containing material layer precursor including at least one of silane, dichlorosilane, and trisilane to the second chamber.

10. The method of claim 1, wherein depositing the first layer pair overlaying the substrate comprises depositing between 10 and 200 first layer pairs onto the substrate while the substrate is seated within the first chamber, and wherein depositing the second layer pair overlaying the first layer pair comprises depositing between 10 and 200 second layer pairs overlaying the first layer pair.

11. The method of claim 1, further comprising cleaning the first chamber during deposition of the second layer pair overlaying the first layer pair.

12. The method of claim 1, further comprising cleaning the second chamber during deposition of the first layer pair overlaying the substrate.

13. The method of claim 1, wherein transferring the substrate from the first chamber comprises carrying the substrate on an end effector of a substrate transfer robot supported for movement within a substrate transfer chamber coupling the first chamber to the second chamber.

14. The method of claim 1, wherein transferring the substrate from the first chamber comprises:
opening a first back-end gate valve coupling the first chamber to a substrate transfer chamber;
advancing an end effector into the first chamber using a substrate transfer robot supported for movement within the substrate transfer chamber;
shifting the substrate with the first layer pair deposited thereon from a substrate support within the first chamber to the end effector;
retracting the end effector carrying the substrate and the first layer pair deposited thereon from the first chamber through the first back-end gate valve;
opening a second back-end gate valve coupling the second chamber to the substrate transfer chamber; and
advancing the end effector carrying the substrate and the first layer pair into the second chamber through the second back-end gate valve.

15. A semiconductor structure formed using the method of claim 1, wherein depositing the first layer pair comprises:
controlling temperature of a silicon germanium material layer during deposition of the silicon germanium material layer using electromagnetic radiation emitted by the silicon germanium material layer received at a pyrometer supported above the first chamber; and
controlling temperature of a silicon material layer during deposition of the silicon material layer using electromagnetic radiation emitted by the silicon material layer at the pyrometer supported above the first chamber; and
wherein depositing the second layer pair comprises:
controlling temperature of the silicon germanium material layer during deposition of the silicon germanium material layer using electromagnetic radiation emitted by the silicon germanium material layer received at a pyrometer supported above the second chamber; and
controlling temperature of the silicon material layer during deposition of the silicon material layer using electromagnetic radiation emitted by the silicon material layer at the pyrometer supported above the second chamber.

16. A semiconductor processing system, comprising:
a substrate transfer chamber housing a substrate transfer robot;
a first chamber coupled to the substrate transfer chamber;
a second chamber coupled to the substrate transfer chamber and therethrough to the first chamber; and
a controller operatively coupled to the semiconductor processing system and responsive to instructions recorded on a memory to:
seat a substrate in a first chamber using the substrate transfer robot;
deposit a first layer pair overlaying the substrate while the substrate is seated in the first chamber;
remove the substrate from the first chamber using the substrate transfer robot;
transfer the substrate to a second chamber using the substrate transfer robot;
seat the substrate in the second chamber using the substrate transfer robot; and
deposit a second layer pair overlaying the first layer pair while the substrate is seated in the second chamber.

17. The semiconductor processing system of claim 16, wherein the first layer pair comprises a silicon germanium material layer overlaying the substrate and a silicon material layer deposited onto the silicon germanium material layer, and wherein the second layer pair comprises a silicon germanium material layer overlaying the first layer pair and a silicon material layer deposited onto the silicon germanium material layer.

18. The semiconductor processing system of claim 17, wherein the instructions further cause the controller to:
control temperature of the silicon germanium material layer during deposition of the silicon germanium material layer using electromagnetic radiation emitted by the silicon germanium material layer received at a pyrometer supported above the first chamber; and
control temperature of the silicon material layer during deposition of the silicon material layer using electromagnetic radiation emitted by the silicon material layer at the pyrometer supported above the first chamber.

19. The semiconductor processing system of claim 17, wherein the instructions further cause the controller to:
control temperature of the silicon germanium material layer during deposition of the silicon germanium material layer using electromagnetic radiation emitted by the silicon germanium material layer received at a pyrometer supported above the second chamber; and
control temperature of the silicon material layer during deposition of the silicon material layer using electromagnetic radiation emitted by the silicon material layer at the pyrometer supported above the second chamber.

20. The semiconductor processing system of claim 16, wherein the instructions further cause the controller to:
open a first back-end gate valve coupling the first chamber to the substrate transfer chamber;
carry the substrate through the first back-end gate valve to a second back-end gate valve coupling the second chamber to the substrate transfer chamber with a substrate transfer robot supported for movement within the substrate transfer chamber;
open the second back-end gate valve; and
carry the substrate with the first layer pair deposited thereon through the second back-end gate valve and into the second chamber using the substrate transfer robot.
